(19) United States
(12) Patent Application Publication
(10) Pub. No.: US 2013/0146337 A1
(43) Pub. Date: Jun. 13, 2013

(54) MULTI-LAYERED PRINTED CIRCUIT BOARD AND MANUFACTURING METHOD THEREOF

(71) Applicant: Samsung Electro-Mechanics Co., Ltd., Gyeonggi-do (KR)

(72) Inventors: Jong-gyu CHIO, Gyeonggi-do (KR); Gil-Yong SHIN, Gyeonggi-do (KR); Kyoung-Ro YOON, Gyeonggi-do (KR)

(73) Assignee: SAMSUNG ELECTRO-MECHANICS CO., LTD., Gyeonggi-do (KR)

(21) Appl. No.: 13/709,993

(22) Filed: Dec. 10, 2012

(30) Foreign Application Priority Data
Dec. 9, 2011 (KR) 10-2011-0131972

(51) Int. Cl. H05K 3/06; H05K 1/02

(52) U.S. Cl. CPC H05K 3/06; H05K 1/0298
USPC 174/251; 216/20

(57) ABSTRACT

A multi-layered printed circuit board and a method of manufacturing the multi-layered printed circuit board are disclosed. The multi-layered printed circuit board in accordance with an embodiment of the present invention includes: an insulation layer; an inner-layer pad disposed inside the insulation layer; an inner-layer circuit wiring disposed inside the insulation layer and formed to be thinner than that of the inner-layer pad; a via connected with the inner-layer pad by penetrating the insulation layer; and an outer-layer circuit wiring formed on an outside surface of the insulation layer.

### CROSS-REFERENCE TO RELATED APPLICATIONS

This application claims the benefit of Korean Patent Application No. 10-2011-0131972, filed with the Korean Intellectual Property Office on Dec. 9, 2011, the disclosure of which is incorporated herein by reference in its entirety.

### BACKGROUND

1. Technical Field

The present invention relates to a multi-layered printed circuit board that can be manufactured in a thin type and a method of manufacturing the multi-layered printed circuit board.

2. Background Art

An increasing number of electronic parts are mounted in electronic devices because printed circuit boards have increasingly become thinner, more integrated, minuter and more functional.

To make a printed circuit board thinner, the insulating material and the inner-layer circuit wiring need to be made thinner. As the inner-layer circuit wiring and the inner-layer pad of a multi-layered printed circuit board are formed by etching a metal layer, the inner-layer circuit wiring have a same thickness as that of the inner-layer pad. In case the inner-layer circuit wiring is formed to be thin, the inner-layer pad becomes thin as well. In the case that the inner-layer pad is thinly formed, the inner-layer pad may be perforated when a via hole is formed by laser processing. In the meantime, in case the inner-layer circuit wiring is formed to be thick, void may be occurred in an interface between a dielectric layer and the inner-layer circuit wiring when the dielectric layer is laminated, and reliability may be jeopardized. Moreover, if the inner-layer circuit wiring is thick, the heat-dissipation efficiency of the board may be lowered.

Korean Patent Publication 2011-0113980 (Publication Date: Oct. 19, 2011) discloses a multi-layer printed circuit board, in which an inner-layer circuit has a same thickness as that of a connection pad.

### SUMMARY

Embodiments of the present invention provide a multi-layered printed circuit board and a manufacturing method thereof that can be manufactured in a thin type and prevent occurrence of void.

An aspect of the present invention features a multi-layered printed circuit board that can include: an insulation layer; an inner-layer pad disposed inside the insulation layer; an inner-layer circuit wiring disposed inside the insulation layer and formed to be thinner than that of the inner-layer pad; a via connected with the inner-layer pad by penetrating the insulation layer; and an outer-layer circuit wiring formed on an outside surface of the insulation layer.

A height of the via protruded from the insulation layer can be the same as a height of the outer-layer circuit wiring.

The multi-layered printed circuit board can be constituted with three layers, which comprise one layer of inner-layer circuit wiring formed inside the insulation layer and two layers of outer-layer circuit wiring formed, respectively, on either surface of the insulation layer.

Another aspect of the present invention features a method of manufacturing a multi-layered printed circuit board that can include: forming a metal layer on one surface of a first insulation layer; etching the metal layer so that an inner-layer circuit wiring becomes thinner than an inner-layer pad; laminating a second insulation layer on one surface of the first insulation layer; forming a via hole in such a way that the inner-layer pad is exposed; and forming a via in the via hole and forming an outer-layer circuit wiring on an outside surface of each of the first and second insulation layers.

The forming of the metal layer on one surface of the first insulation layer can include: forming a seed layer on one surface of a carrier; laminating the first insulation layer on the seed layer; and forming a metal layer on one surface of the first insulation layer.

The etching of the metal layer so that the inner-layer circuit wiring becomes thinner than the inner-layer pad can include: forming an etching resist in an area on one surface of the metal layer where the inner-layer pad is to be formed; reducing a thickness of the metal layer by etching the metal layer; forming an etching resist in an area where the inner-layer pad is to be formed and in an area where the inner-layer circuit wiring is to be formed; and forming the inner-layer pad and the inner-layer circuit wiring by etching the metal layer.

The forming of the via hole can include: removing a carrier laminated on the first insulation layer and the second insulation layer; and forming a via hole in the first insulation layer and the second insulation layer so as to correspond to the inner-layer pad.

The forming of the via and the outer-layer circuit wiring can include: forming a plating resist on a seed layer of each of the first insulation layer and the second insulation layer; forming a plated layer on the seed layer; removing the plating resist; and forming the via and the outer-layer circuit wiring by flash-etching the seed layer.

The method of manufacturing a multi-layered printed circuit board can also include, after the forming of the via and the outer-layer circuit wiring, forming a solder resist on an outside surface of each of the first insulation layer and the second insulation layer.

A height of the via protruded from an insulation layer can be the same as a height of the outer-layer circuit wiring.

The multi-layered printed circuit board can be constituted with three layers, which comprise one layer of inner-layer circuit wiring formed inside an insulation layer and two layers of outer-layer circuit wiring formed, respectively, on either surface of the insulation layer.

### BRIEF DESCRIPTION OF THE DRAWINGS

FIG. 1 shows a multi-layered printed circuit board in accordance with an embodiment of the present invention.

FIGS. 2 to 16 show a method of manufacturing a multi-layered printed circuit board in accordance with an embodiment of the present invention.

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention. Throughout the description of the present invention, when describing a certain technology is determined to evade the point of the present invention, the pertinent detailed description will be omitted.

Hereinafter, a multi-layered printed circuit board in accordance with an embodiment of the present invention will be described with reference to the accompanying drawings.

FIG. 1 shows a multi-layered printed circuit board in accordance with an embodiment of the present invention.

Referring to FIG. 1, the multi-layered printed circuit board can include an insulation layer 120, an inner-layer pad 131, an inner-layer circuit wiring 133, a via 163 and an outer-layer circuit wiring 165.

The insulation layer 120 can be formed by impregnating a fiber in epoxy. Moreover, it is possible to use a prepreg, which is made to be in a semi-hardened state by applying thermosetting resin on a glass fiber, for the insulation layer 120.

The inner-layer pad 131 and the inner-layer circuit wiring 133 can be disposed inside the insulation layer 120. Specifically, a metal layer, such as a copper foil, can be laminated on one surface of a first insulation layer 121 and then etched to form the inner-layer pad 131 and the inner-layer circuit wiring 133. By laminating a second insulation layer 123 on one surface of the first insulation layer 121, the inner-layer pad 131 and the inner-layer circuit wiring 133 can be disposed in between the first and second insulation layers 121, 123. Here, the first insulation layer 121 and the second insulation layer 123 can constitute one insulation layer 120.

A thickness (H₂) of the inner-layer circuit wiring 133 can be formed to be smaller than a thickness (H₁) of the inner-layer pad 131. For example, an etching resist is formed in an area of a metal layer where the inner-layer pad 131 is to be formed, and the metal layer is etched to reduce the thickness of a metal layer 130. Then, an etching resist for forming the inner-layer circuit wiring 133 is formed on the etched metal layer, and then the etched metal layer is etched. Through this process, the thickness (H₂) of the inner-layer circuit wiring 133 can be formed to be smaller than the thickness (H₁) of the inner-layer pad 131.

The inner-layer pad 131 can have the thickness of approximately 5-35 um. The thickness of the inner-layer circuit wiring 133 can be formed to be smaller than approximately 20% of the thickness (H₁) of the inner-layer pad 131. Here, as the metal layer is etched, there can be a difference in thickness between the inner-layer circuit wiring 133 and the inner-layer pad 131. This will be described later in more detail.

The via 163 can be connected with the inner-layer pad 131 by penetrating the insulation layer 120. The via 163 can be formed by forming a via hole 151 that penetrates the insulation layer 120 so as to expose the inner-layer pad 131 and then by fill-plating the via hole 151.

The outer-layer circuit wiring 165 can be formed on an outside surface of the insulation layer 120. The outer-layer circuit wiring 165 can be formed by plating the via hole 151 and the insulation layer 120 and then etching a plated layer. The outer-layer circuit wiring 165 and the via 163 can be formed simultaneously by etching the plated layer.

The height of the via 163 protruded from the insulation layer 120 can be the same as the height of the outer-layer circuit wiring 165. This is because the via 163 and the outer-layer circuit wiring 165 are formed by etching a plated layer 160.

As described above, the thickness (H₂) of the inner-layer circuit wiring 133 can be thinly formed while the thickness (H₁) of the inner-layer pad 131 is sufficiently provided. Accordingly, it becomes possible to prevent the inner-layer pad 131 from being perforated when the via hole 151 is formed using, for example, a laser drill.

Moreover, the thickness of the multi-layered printed circuit board can be significantly reduced because the thickness (H₂) of the inner-layer circuit wiring 133 can be formed to be as thin as possible without considering the thickness (H₁) of the inner-layer pad 131.

Moreover, the inner-layer pad 131 is connected with the via 163 to perform a function of cooling the board. Since the inner-layer pad 131 is formed to be thicker than the inner-layer circuit wiring 133, it is possible to improve a cooling efficiency of the board. Furthermore, since the inner-layer pad 131 becomes relatively larger as the printed circuit board becomes thinner, the cooling efficiency can be further improved in a thin board.

Hereinafter, a manufacturing method of the multi-layered printed circuit board configured as described above in accordance with an embodiment of the present invention will be described.

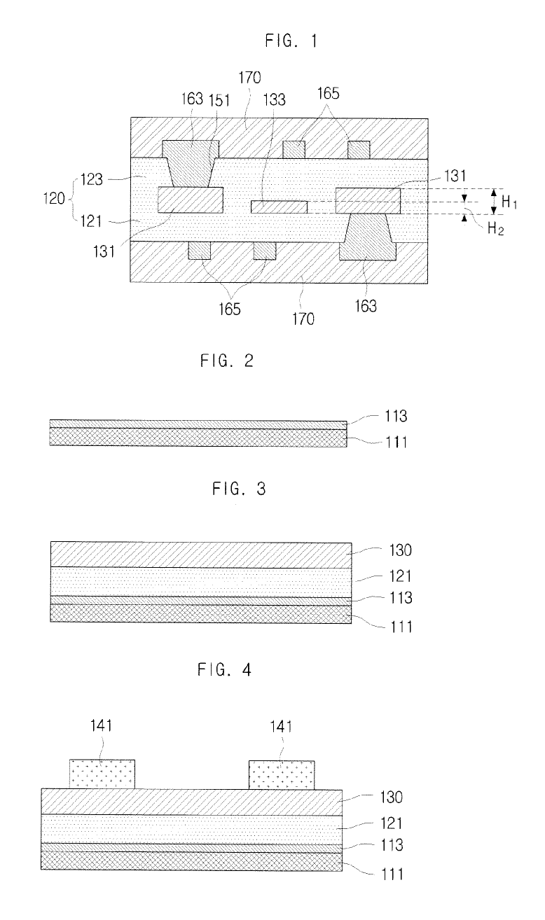

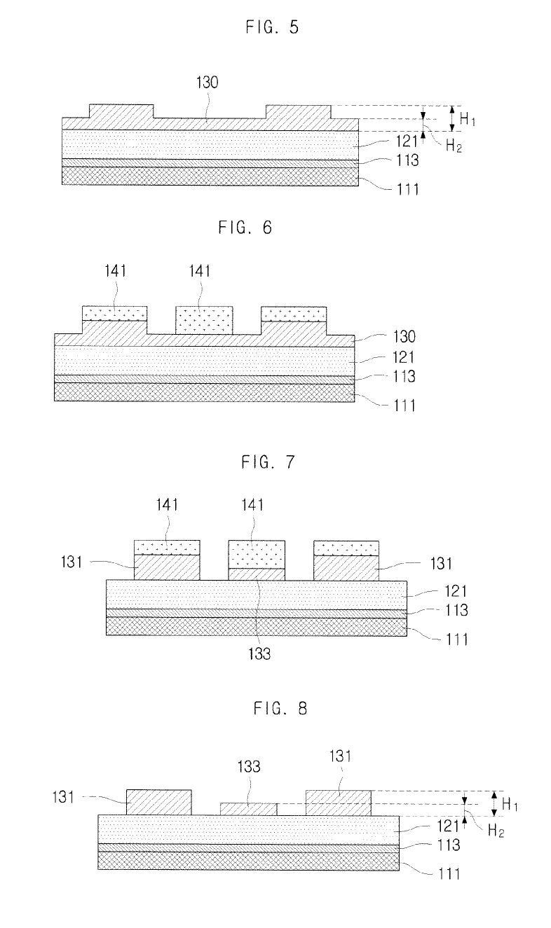

FIGS. 2 to 16 show a method of manufacturing a multi-layered printed circuit board in accordance with an embodiment of the present invention.

Referring to FIGS. 2 and 3, the metal layer 130 is formed on one surface of the first insulation layer 121. For example, a seed layer 113 is formed on one surface of a carrier 111. The seed layer 113 is for forming the plated layer 160 in order to form the outer-layer circuit wiring 165 after the carrier 111 is removed. The first insulation layer 121 is laminated on the seed layer 113, and the metal layer 130 is formed on one surface of the first insulation layer 121. The metal layer 130 can be formed with a thickness of approximately 5-35 um. The metal layer 130 can be formed with a variety of materials, for example, a copper foil.

Referring to FIGS. 4 to 8, the metal layer 130 is etched so that the thickness (H₂) of the inner-layer circuit wiring 133 is smaller than the thickness (H₁) of the inner-layer pad 131. For example, an etching resist 141 is formed in an area of the metal layer 130 where the inner-layer pad 131 is to be formed. The metal layer 130 is exposed, developed and etched to reduce the thickness of a metal layer 130. The metal layer 130 can be etched to have an appropriate thickness, considering the thickness of the inner-layer circuit wiring 133.

Here, the area where the inner-layer pad 131 is to be formed can have a same thickness as that of the metal layer 130, and the etched area of the metal layer can have a same thickness as that of the inner-layer circuit wiring 133, which is to be formed through a process described below. For example, the area where the inner-layer pad 131 is to be formed can be formed with the thickness of approximately 5-35 um, and the etched area of the metal layer can be formed with the thickness of approximately 20% or less of that of the area where the inner-layer pad 131 is to be formed.

Then, the etching resist 141 can be formed where the inner-layer pad 131 is to be formed and where the inner-layer circuit wiring 133 is to be formed. By exposing, developing and etching the metal layer 130, the inner-layer pad 131 and the inner-layer circuit wiring 133 can be formed. The inner-layer pad 131 can be formed to have the thickness of approximately 5-35 um, and the inner-layer circuit wiring 133 can be formed to have the thickness of approximately 20% or less of that of the inner-layer pad 131. The inner-layer pad 131 can have a sufficient thickness, and the inner-layer circuit wiring 133 can be thinly formed. Accordingly, it is possible to design the inner-layer circuit wiring 133 to be thin regardless of the thickness of the inner-layer pad 131. Moreover, it is not necessary to form the inner-layer circuit wiring 133 to be inevitably thick in order to secure the thickness of the inner-layer pad 131. Furthermore, as the inner-layer circuit wiring 133 is thinly formed, the multi-layered printed circuit board can be formed in a thin type.

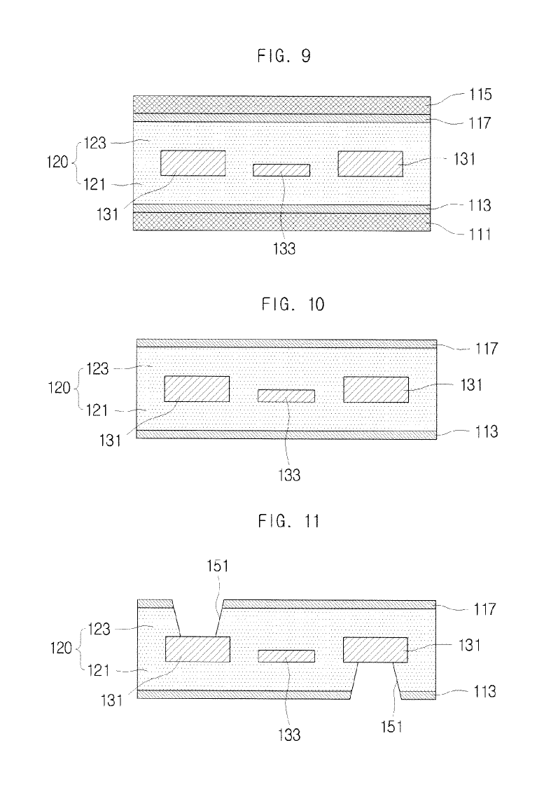

Referring to FIG. 9, the second insulation layer 123 is laminated on one surface of the first insulation layer 121. Here, a seed layer 117 is formed on one surface of the second insulation layer 123, and a carrier 115 is laminated on the seed layer 117 of the second insulation layer 123. Moreover, the inner-layer pad 131 and the inner-layer circuit wiring 133 are disposed in between the first insulation layer 121 and the second insulation layer 123. Here, since a surface area of the inner-layer circuit wiring 133 is reduced by forming the inner-layer circuit wiring 133 to be sufficiently thin, it is possible to prevent void from occurring on an interface of the inner-layer circuit wiring 133 when the first insulation layer 121 and the second insulation layer 123 are laminated. Furthermore, it is possible to secure the reliability of the multi-layered printed circuit board.

Referring to FIGS. 10 and 11, the via hole 151 is formed in such a way that the inner-layer pad 131 is exposed. For example, the carriers 111, 115 laminated on the first insulation layer 121 and the second insulation layer 123, respectively, are removed. Here, the seed layers 113, 117 are formed on outside surfaces of the first insulation layer 121 and the second insulation layer 123, respectively. By use of, for example, a laser drill, the via hole 151 can be formed in the first insulation layer 121 and the second insulation layer 123 so as to correspond to the inner-layer pad 131. Here, since the inner-layer pad 131 has a sufficient thickness (H₁), the inner-layer pad 131 can be prevented from being perforated when the via hole 151 is formed by the laser drill. Therefore, when the thin multi-layered printed circuit board is fabricated, any perforation problem of a connection pad is solved while the thickness (H₁) of the inner-layer circuit wiring 133 is significantly reduced.

Moreover, the seed layers 113, 117 can be formed on lateral side walls of the via hole 151. The see layers 113, 117 are configured to allow the via hole 151 to be readily plated. Referring to FIGS. 12 to 15, the via 163 can be formed in the via hole 151, and the outer-layer circuit wiring 165 can be formed on outside surfaces of the first insulation layer 121 and the second insulation layer 123.

For example, a plating resist 153 is formed on the seed layers 113, 117 that are formed on the first insulation layer 121 and the second insulation layer 123, respectively. Here, the plating resist 153 can be formed at areas excluding where the via holes 151 are formed and the outer-layer circuit wiring 165 is to be formed. The plated layer 160 is formed on the seed layer 113, 117. Here, the plated layer 160 can be formed by electrolytic plating. Here, the plated layer 160 can be fill-plated so as to fill the via hole 151. As shown in FIG. 14, the plating resist 153 is removed after the plated layer 160 is completely formed.

As shown in FIG. 15, the via 163 and the outer-layer circuit wiring 165 can be formed by flash-etching the seed layer 113, 117. After forming the via 163 and the outer-layer circuit wiring 165, the via 163 and the outer-layer circuit wiring 165 can be surface-treated.

Here, the height of the via 163 protruded from the insulation layer 120 and the height of the outer-layer circuit wiring 165 can be made to be the same.

Referring to FIG. 16, a solder resist 170 can be formed on outside surfaces of the first insulation layer 121 and the second insulation layer 123, respectively, after the via 163 and the outer-layer circuit wiring 165 are formed.

As described above, since the inner-layer circuit wiring 133 is formed to be thinner than that of the inner-layer pad 131, the multi-layered printed circuit board can be manufactured in a tin form. Moreover, the inner-layer circuit wiring 133 does not need to be formed unnecessarily thick in order to secure the thickness of the inner-layer pad 131. The inner-layer circuit wiring 133 can be formed to be sufficiently thin while preventing the inner-layer pad 131 from being perforated when the via hole is processed. Moreover, since the surface area of the inner-layer circuit wiring 133 is reduced as the inner-layer circuit wiring 133 becomes thinner, void can be prevented from occurring when the insulation layer 120 is laminated.

Moreover, the inner-layer pad 131 can function to cool the board, by being connected with the via 163. As this inner-layer pad 131 is formed to be thicker than the inner-layer circuit wiring 133, the cooling efficiency of the board can be improved. Furthermore, since the inner-layer pad 131 becomes relatively larger as the printed circuit board becomes thinner, the cooling efficiency in the thin board can be further improved.

The multi-layered printed circuit board in accordance with an embodiment of the present invention can be constituted with three layers, which include one layer of inner-layer circuit wiring formed inside the insulation layer and two layers of outer-layer circuit wiring formed, respectively, on either surface of the insulation layer. As the multi-layered printed circuit board is formed with three layers, the board can be manufactured as thin as possible.

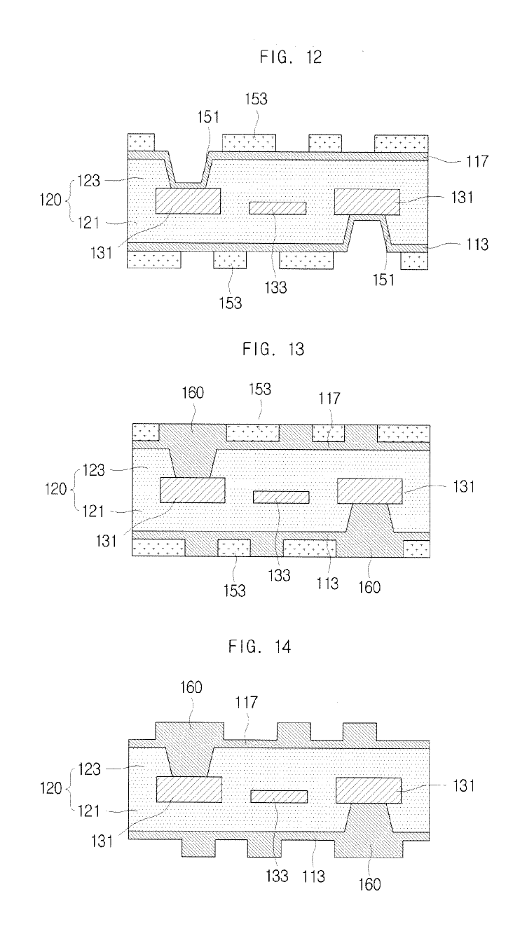

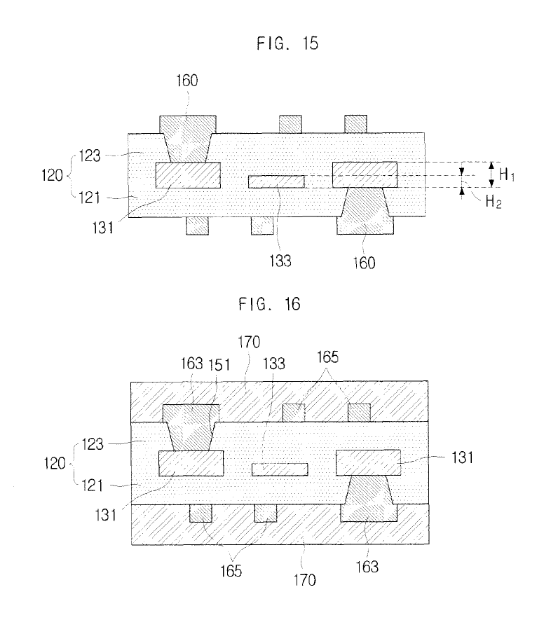

Moreover, the multi-layered printed circuit board can be constituted with multiple layers, which include 2 or more layers of inner-layer circuit wiring formed inside the insulation layer and two layers of outer-layer circuit wiring formed, respectively, on either surface of the insulation layer. For example, in FIG. 13, an etching resist is formed in the via hole area of the metal layer 160, and the area where the outer-layer circuit wiring is to be formed is flash-etched. Here, the outer-layer circuit wiring can be formed to be thinner than the via. Then, the insulation layer laminated with the metal layer can be laminated on both surfaces of the insulation layer, and the outer-layer circuit wiring can be formed by etching the metal layer. By repeating the above process, the multi-layered printed circuit board can be constituted with multiple layers.

While the present invention has been described with reference to a certain embodiment, the embodiment is for illustrative purposes only and shall not limit the invention. It is to be appreciated that those skilled in the art can change or modify the embodiment without departing from the scope and spirit of the invention.

It shall be also appreciated that a very large number of embodiments other than that described herein are possible within the scope of the present invention, which shall be defined by the claims appended below.

1. A multi-layered printed circuit board comprising:
an insulation layer;
an inner-layer pad disposed inside the insulation layer;
an inner-layer circuit wiring disposed inside the insulation layer and formed to be thinner than that of the inner-layer pad;
a via connected with the inner-layer pad by penetrating the insulation layer; and
an outer-layer circuit wiring formed on an outside surface of the insulation layer.

2. The multi-layered printed circuit board of claim 1, wherein a height of the via protruded from the insulation layer is the same as a height of the outer-layer circuit wiring.

3. The multi-layered printed circuit board of claim 1, constituted with three layers, which comprise one layer of inner-layer circuit wiring formed inside the insulation layer and two layers of outer-layer circuit wiring formed, respectively, on either surface of the insulation layer.

4. A method of manufacturing a multi-layered printed circuit board, comprising:
forming a metal layer on one surface of a first insulation layer;
etching the metal layer so that an inner-layer circuit wiring becomes thinner than an inner-layer pad;
laminating a second insulation layer on one surface of the first insulation layer;
forming a via hole in such a way that the inner-layer pad is exposed; and
forming a via in the via hole and forming an outer-layer circuit wiring on an outside surface of each of the first and second insulation layers.

5. The method of claim 4, wherein the forming of the metal layer on one surface of the first insulation layer comprises:
forming a seed layer on one surface of a carrier;
laminating the first insulation layer on the seed layer; and
forming a metal layer on one surface of the first insulation layer.

6. The method of claim 4, wherein the etching of the metal layer so that the inner-layer circuit wiring becomes thinner than the inner-layer pad comprises:
forming an etching resist in an area on one surface of the metal layer where the inner-layer pad is to be formed;
reducing a thickness of the metal layer by etching the metal layer;
forming an etching resist in an area where the inner-layer pad is to be formed and in an area where the inner-layer circuit wiring is to be formed; and
forming the inner-layer pad and the inner-layer circuit wiring by etching the metal layer.

7. The method of claim 4, wherein the forming of the via hole comprises:
removing a carrier laminated on the first insulation layer and the second insulation layer; and
forming a via hole in the first insulation layer and the second insulation layer so as to correspond to the inner-layer pad.

8. The method of claim 4, wherein the forming of the via and the outer-layer circuit wiring comprises:
forming a plating resist on a seed layer of each of the first insulation layer and the second insulation layer;
forming a plated layer on the seed layer;
removing the plating resist; and
forming the via and the outer-layer circuit wiring by flash-etching the seed layer.

9. The method of claim 4, further comprising, after the forming of the via and the outer-layer circuit wiring, forming a solder resist on an outside surface of each of the first insulation layer and the second insulation layer.

10. The method of claim 4, wherein a height of the via protruded from an insulation layer is the same as a height of the outer-layer circuit wiring.

11. The method of claim 4, wherein the multi-layered printed circuit board is constituted with three layers, which comprise one layer of inner-layer circuit wiring formed inside an insulation layer and two layers of outer-layer circuit wiring formed, respectively, on either surface of the insulation layer.
